(19) United States
(12) Patent Application Publication
(10) Pub. No.: US 2007/0029661 A1
(43) Pub. Date: Feb. 8, 2007

(54) Power plane design and jumper wire bond for voltage drop minimization

(75) Inventors: Stanley Craig Beddingfield, McKinney, TX (US); Kevin Peter Lyne, Plano, TX (US); Peter Harper, Lucas, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/198,543

(22) Filed: Aug. 4, 2005

(51) Int. Cl. H01L 23/52; H01L 21/44

(52) U.S. Cl. 257/691; 257/698; 257/700; 438/614

(57) ABSTRACT

According to one embodiment of the invention, a power system for a die comprises a plurality of supply voltage lines, a plurality of ground lines, a plurality of metallized rails, and a via. Each of the plurality of supply voltage lines are in communication with at least one supply voltage pad. Each of the plurality of ground lines are in communication with at least one ground pad. The plurality of ground lines are interlaced with the plurality of supply voltage lines. The plurality of metallized rails are disposed across the plurality of supply voltage lines and the plurality of ground lines. The via communicatively couples at least one of the plurality of metallized rails to at least one of the supply voltage lines or at least one of the ground lines.

### TECHNICAL FIELD OF THE INVENTION

This invention relates generally to the field of semiconductor devices and, more particularly, to a power plane design and jumper wire bond for voltage drop minimization.

### BACKGROUND OF THE INVENTION

Integrated circuits may include a variety of different circuitry configurations. With the decrease in the geometries and increased complexities in such circuitries, the current (I) flowing through various portions of the circuitry may encounter resistance (R), resulting in voltage or IR drops. Such resistance may negatively impact the performance of the circuitry and/or form undesirable “hot spots” in portions of the circuitry.

### SUMMARY OF THE INVENTION

According to one embodiment of the invention, a power system for a die comprises a plurality of supply voltage lines, a plurality of ground lines, a plurality of metallized rails, and a via. Each of the plurality of supply voltage lines are in communication with at least one supply voltage pad. Each of the plurality of ground lines are in communication with at least one ground pad. The plurality of ground lines are interlaced with the plurality of supply voltage lines. The plurality of metallized rails are disposed across the plurality of supply voltage lines and the plurality of ground lines. The via communicatively couples at least one of the plurality of metallized rails to at least one of the supply voltage lines or at least one of the ground lines.

Certain embodiments of the invention may provide numerous technical advantages. For example, a technical advantage of one embodiment may include the capability to provide parallel paths of power communication to portions of circuitry. Other technical advantages of other embodiments may include the capability to provide a uniform and complete power distribution by tying together appropriate bond pads, to extend caps over a passivation layer to allow extra area for bonding, or to deposit metallized rails in the same layer as a layer in which caps are deposited on bottom pads.

Although specific advantages have been enumerated above, various embodiments may include all, some, or none of the enumerated advantages. Additionally, other technical advantages may become readily apparent to one of ordinary skill in the art after review of the following figures and description.

### BRIEF DESCRIPTION OF THE DRAWINGS

For a more complete understanding of example embodiments of the present invention and its advantages, reference is now made to the following description, taken in conjunction with the accompanying drawings, in which:

FIG. 1 shows a side-cross sectional view of a conventional power system;

FIG. 2 shows a system, according to an embodiment of the invention;

FIG. 3 shows a side view of a power system with stacked dies, according to another embodiment of the invention;

FIG. 4 shows a top view of a power system, according to yet another embodiment of the invention;

FIGS. 5A, 5B, 5C, and 5D show side views of bond pads, according to embodiments of the invention.

### DETAILED DESCRIPTION OF EXAMPLE EMBODIMENTS OF THE INVENTION

It should be understood at the outset that although example embodiments of the present invention are illustrated below, the present invention may be implemented using any number of techniques, whether currently known or in existence. The present invention should in no way be limited to the example embodiments, drawings, and techniques illustrated below, including the embodiments and implementation illustrated and described herein. Additionally, the drawings are not necessarily drawn to scale.

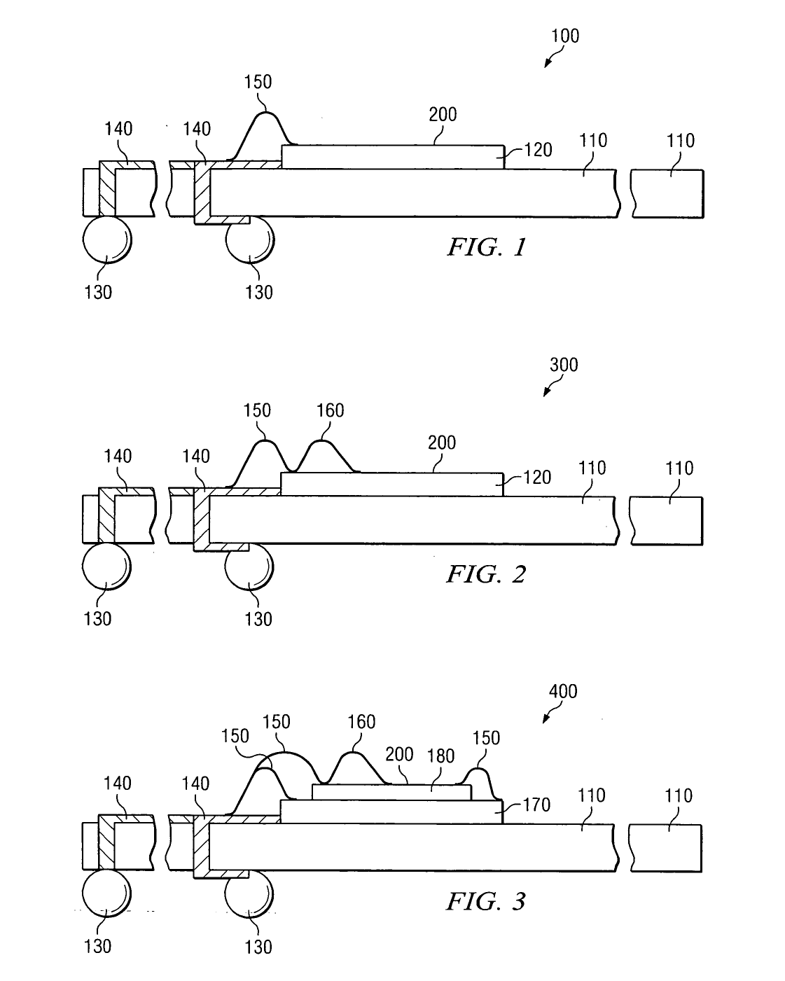

FIG. 1 shows a side-cross sectional view of a conventional power system 100. The conventional power system 100 include solder balls 130, traces 140, and a wire bond connection 150. With the conventional power system 100, electrical current or power may be communicated to a die 120 by traveling from the solder balls 130 (e.g., ball-grid array balls) through the traces 140 and the wire bond connections 150 to a surface perimeter of the die 120, for example, a pad (not explicitly shown) . Current, communicated away from the die 120, may take an opposite path. The die 120 may include any of a variety of circuitries 200 embedded within its surface. From the surface perimeter of the die 120 or the pad, the current may travel through paths (e.g., metal paths) in the circuitry 200 to a desired location within the circuitry 200.

With the decrease in the geometries in the circuitry 200 and the increased complexity in the circuitry 200, voltage or IR drops may occur in various portions of the circuitry 200, for example, due to increased resistance. As used herein, “IR drop” may generally refer to a voltage drop that is associated with the electrical resistance (R) of a current flow (I). Such resistance may negatively impact the performance of the circuitry 200 and/or form undesirable “hot spots” in the portions of the circuitry 200. Accordingly, teachings of some embodiments of the invention recognize a system and method for compensating for such reduced geometries. Additionally teachings of other embodiments of the invention recognize a system and method of alleviating undesirable hot spots in the circuitry 200.

FIG. 2 shows a system 300, according to an embodiment of the invention. In FIG. 2, a jumper wire 160 has been provided over a surface of the die 120 to provide a parallel path of communication (e.g., communication of the circuit or power) between inner portions of the circuitry 200 on the die 120 and a perimeter of the die 120 or pad (not explicitly shown). With these parallel paths of communication, the current from the wire bond connection 150 may flow not only through the circuitry 200, but also through the jumper wire 160. And, the resistance through the jumper wire 160 to the portion of the circuitry 200 may have a lower resistance than through the paths of circuitry 200. As one example, the jumper wire 160 may be coupled to hot spots in the inner portions of the circuitry to provide and/or receive the electrical current.

FIG. 3 shows a side view of a power system 400 with stacked dies, according to another embodiment of the invention. In the system 400 of the FIG. 3, a second die 180 is stacked on a first die 170. As an example, the first die 170 may be Dynamic Random Access Memory (DRAM) and the second die 180 may be an OMAP (TM), a technology of Texas Instruments. In this embodiment, the wire bond connections 150 are coupled to the perimeters of the first die 170 and the second die 180. Similar to that described in FIG. 2, the jumper wire 160 extends over a surface of the second die 180 to provide a parallel path of communication (e.g., communication of the circuit or power) between inner portions of the circuitry 200 on the second die 180 and a perimeter of the second die 180 or pad (not explicitly shown).

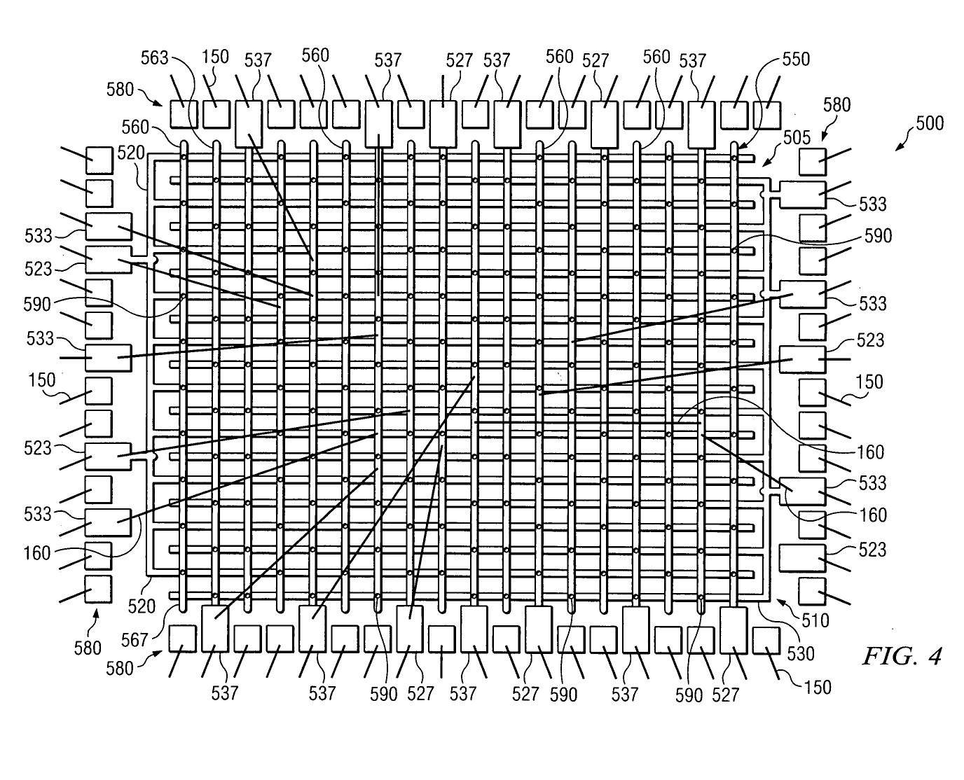

FIG. 4 shows a top view of a power system 500, according to yet another embodiment of the invention. The system 500 of FIG. 4 includes a grid 505, a plurality of bond pads 580, and jumper wires 160. Through combinations of couplings, described below, and the jumper wires 160, the bond pads 580 are in communication the grid 505, for example, to provide or receive electrical current or power. Although not explicitly shown, the power system 500 may be in communication with a die that provides the foundation for a variety of semiconductor features, including but not limited to, analog and/or digital circuits such as digital to analog converters, computer processor units, amplifiers, digital signal processors, controllers, transistors, or other semiconductor features or other integrated circuits.

The bond pads 580 may be in communication with the wire bond connections 150 in a manner similar to that described above with reference to FIGS. 1, 2, and 3. The bond pads 580 may be a power supply voltage (VDD) bond pad, a ground (VSS) bond pad, or have other suitable use. Accordingly, the bond pads 580 in this embodiment include first VSS bond pads 523, first VDD bond pads 533, second VSS bond pads 527, and second VDD bond pads 537, disposed around the perimeter of the grid 505.

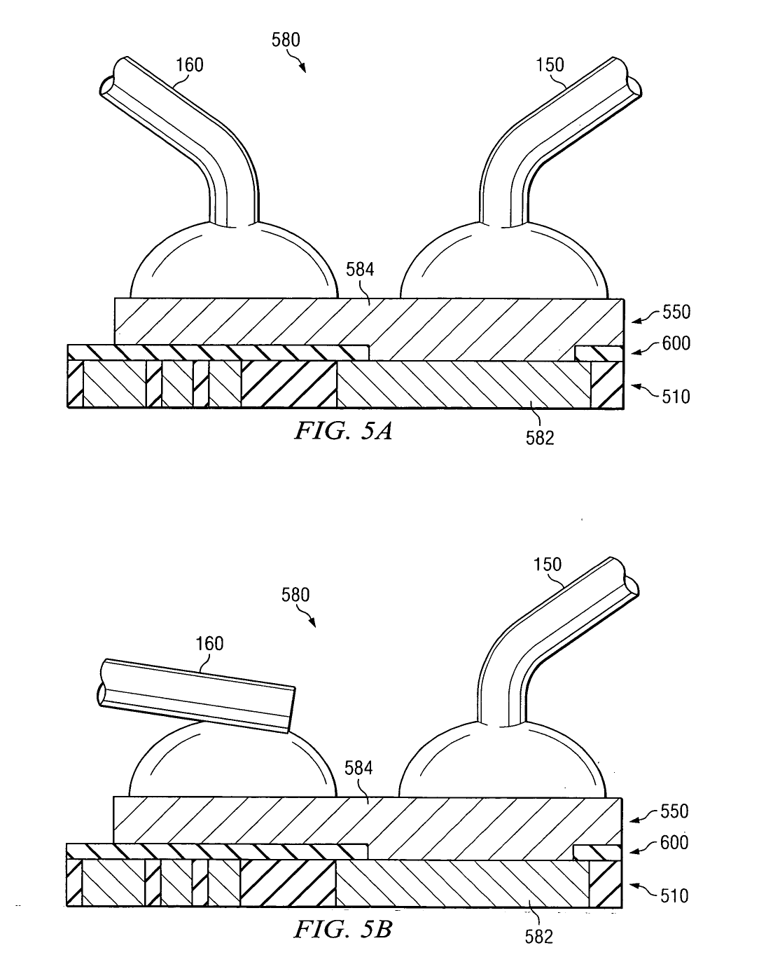

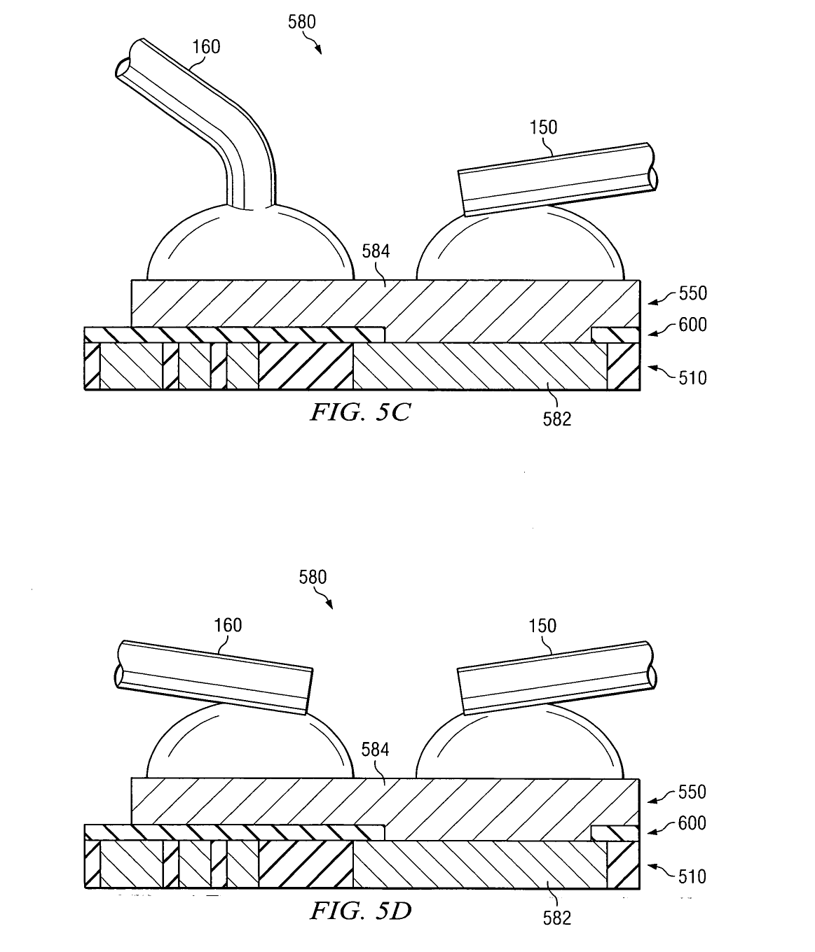

The grid 505 includes a lower layer 510 and an metallized layer 550. Although not explicitly shown, a passivation layer may be disposed between the lower layer 510 and the metallized layer 550. Further details of the passivation layer will be described below with reference to FIG. 5A.

The lower layer 510 in FIG. 4 includes ten power supply voltage or VDD lines 530 and ten ground or VSS lines 520. The VDD lines 530 and VSS lines 520 in the lower layer 510 are interlaced in a comb-like manner between one another. Each of the VDD lines 530 is coupled to one or more of the first VDD bond pads 533. Each of the VSS lines 520 is coupled to with one or more of the first VSS bond pads 523.

In this embodiment, the metallized layer 550 includes eighteen metallized rails 560 that are disposed across the VDD lines 530 and VSS lines 520. The metallized rails comprise VDD metallized rails 563 and VSS metallized rails 567. At least some of the VDD metallized rails 563 are coupled to second VDD pads 537. And, at least some oft the VSS metallized rails 567 are coupled to the second VSS bond pads 527. A plurality of vias 590 couple the VDD metallized rails 563 to the VDD lines 530 and the VSS metallized rails 567 to the VSS lines 520. Utilizing such vias 590 and the metallized rails 560, all of the first VSS bond pads 523 and the second VSS bond pads 527 may be in communication with one another. Additionally, all of the first VDD bond pads 533 and the second VDD bond pads 537 may be in communication with one another. Accordingly, the grid 505 may compensate for situations when a circuitry 200 in communication with the grid 505 has more resistance in particular areas by providing a uniform and complete power distribution.

In a manner similar to that described above with reference to FIG. 2, the jumper wires 160 may provide a parallel path for communications to various interior portions of the grid 505. The jumper wires 160 in FIG. 4 are shown disposed between the bond pads 580 (e.g., VSS bond pads 523, the first VDD bond pads 533, the second VSS bond pads 527, and the second VDD bond pads 537) and the metallized rails 560. Such jumper wires 160, for example, may be coupled to the metallized rails 560 in proximity to “hot spots” to facilitate additional paths of communication. Additionally, jumper wires may be disposed between two VDD metallized rails 563 or two VSS metallized rails 567. In coupling the jumper wires 160 to the metallized rails 560, any of a variety of coupling techniques may be utilized, including, but not limited to reverse stud stitch bonding.

As can be seen in FIG. 4, some bond pads 580 are directly coupled to the grid 505, for example, through the metallized rail 560, a VDD line 530, or a VSS line 520. Other bond pads 580 are coupled to the grid utilizing the jumper wires 160. Still yet other bond pads 580 are coupled to the grid 505 through a combination of direct coupling through the metallized rail 560, VDD line 530, or VSS line 520, and coupling through the jumper wires 160.

FIGS. 5A, 5B, 5C, and 5D show side views of bond pads 580, according to embodiments of the invention. The bond pad 580, for example, may be any of the first VDD bond pads 533, the first VSS bond pad 523, the second VDD bond pad 537, and the second VSS bond pad 527. The bond pad 580 includes a bottom pad 582 and a cap 584 in communication with one another. The bond pad 580 is disposed in three layers: the lower layer 510, a passivation layer 600, and the metallized layer 550. Suitable materials for the bottom pad 582, include, but are not limited to copper. Suitable materials for the cap 584 include, but are not limited to aluminum.

In operation, the bottom pad 582, the VDD lines 530 and the VSS lines 520 may initially be deposited in the lower layer followed by a deposition of the passivation layer 600. Then, the caps 584 and the metallized rails 560 (not explicitly shown) may be deposited in the metallized layer 550.

As can be seen in FIG. 5A, the caps 584 extend over a portion of the passivation layer 600. This cap 584 allows an extra area for bonding, for example, as compared to the bonding area available for only the bottom pad 582. Accordingly, the bond pad 580 has room for both the wire bond connection 150 and the jumper wire 160.

FIG. 5A, 5B, SC, and SD additionally show various bonding techniques that may be utilized. In FIG. 5A, both the wire bond connection 150 and the jumper 160 show a standard wire bond. FIG. 5B shows a stud-stitch bond (SSB) with the jumper 160 and standard bond with the wire bond connection 150; FIGURE SC shows a SSB with the wire bond connection 150 and a standard bond with the jumper 160; and FIG. 5D shows a SSB with both the wire bond connection 150 and the jumper 160.

Although the present invention has been described with several embodiments, a myriad of changes, variations, alterations, transformations, and modifications may be suggested to one skilled in the art, and it is intended that the present invention encompass such changes, variations, alterations, transformation, and modifications as they fall within the scope of the appended claims.

What is claimed is:

1. A power system for a die, the power system comprising:
a plurality of supply voltage lines, each of the plurality of supply voltage lines in communication with at least one supply voltage pad; and
a plurality of ground lines, each of the plurality of ground lines in communication with at least one ground pad, the plurality of ground lines interlaced with the plurality of supply voltage lines.

2. The power grid of claim 1, further comprising:
a plurality of metallized rails disposed across the plurality of supply voltage lines and the plurality of ground lines; and
a via communicatively coupling at least one of the plurality of metallized rails to at least one of the supply voltage lines or at least one of the ground lines.

3. The power grid of claim 2, wherein:
the plurality of metallized rails comprise supply voltage metallized rails and ground metallized rails, each of the supply voltage metallized rails in communication with at least one of the supply voltage lines and each of the ground metallized rails in communication with at least one of the ground lines.

4. The power grid of claim 3, further comprising:
at least one jumper wire extending between at least one of the supply voltage metallized rails and one of the at least one supply voltage pads to establish a parallel path of communication.

5. The power grid of claim 3, further comprising:
at least one jumper wire extending between at least one of the ground metallized rails and one of the at least one supply voltage pads to establish a parallel path of communication.

6. The power grid of claim 5, further comprising:
at least one jumper wire extending between at least one of the supply voltage metallized rails and one of the at least one supply voltage pads to establish another parallel path of communication.

7. The power grid of claim 3, further comprising:
a jumper wire extending between two supply voltage metallized rails or two ground metallized rails to establish communication between the two supply voltage metallized rails or the two ground metallized rails.

8. The power grid of claim 3, wherein
at least one of the supply voltage metallized rails is directly coupled to at least one of the at least one supply voltage pads; and
at least one of the ground metallized rails is directly coupled to at least one of the at least one ground pads.

9. The power grid of claim 8, wherein
the at least one supply voltage pad is a plurality of supply voltage pads;
the at least one ground pad is a plurality of ground pads;
the supply voltage metallized rails establish communication between all of the plurality of supply voltage pads; and
the ground voltage rails establish communication between all of the plurality of supply voltage pads;

10. The power grid of claim 3, wherein the plurality of supply voltage lines and the plurality of ground lines are disposed in a lower layer and the plurality of metallized rails are diposed in an metallized layer, the power grid further comprising:
a passivation layer disposed between the lower layer and the metallized layer; and
a plurality of vias disposed through the passivation layer to allow each of the supply voltage metallized rails to be in communication with at least one of the supply voltage lines and each of the ground metallized rails to be in communication with at least one of the ground lines.

11. A method of creating a power system for a die, the method comprising:
depositing a plurality of bottom pads, a plurality of supply voltage lines, and a plurality of ground lines in a lower layer;
depositing a cap on at least some of the plurality of bottom pads and a plurality of metallized rails across the plurality of supply voltage lines and the plurality of ground lines in an metallized layer; and
coupling a wire bond connection to at least one of the caps of the plurality of bottom pads.

12. The method of claim 11, further comprising:
depositing a passivation layer on top of the lower layer prior to depositing the metallized layer, wherein depositing the metallized layer further includes depositing a portion of a cap over at least a portion of the passivation layer.

13. The method of claim 11, wherein the plurality of metallized rails comprise supply voltage metallized rails and ground metallized rails, further comprising:
coupling, with at least a first via, at least one of the supply voltage metallized rails to at least one of the plurality of supply voltage lines to establish communication between the at least one of the supply voltage metallized rails and the at least one of the plurality of supply voltage lines; and
coupling, with at least a second via, at least one of the ground metallized rails to at least one of the plurality of ground lines to establish communication between the at least one of ground metallized rails and the at least one of the plurality of ground lines.

14. The method of claim 13, wherein the placement of the caps on the bottom pads form supply voltage pads and ground pads , further comprising:
coupling, with at least a first jumper wire, at least one supply voltage pad to the at least one of the supply voltage metallized rails to form a parallel path of communication with the at least one of the supply voltage metallized rails; and
coupling, with at least a second jumper wire, at least one ground pad to the at least one of the ground metallized rails to form a parallel path of communication with the at least one of the ground rails.

15. A power system for a die, the power system comprising:
a supply voltage pad or a ground pad disposed on a periphery of the die;
an inner portion operable disposed within a periphery of the die and to communicate a current to or from an inner portion of the die; and
a jumper wire extending from the supply voltage pad or the ground pad to the interior portion.

16. The power system of claim 15, wherein the jumper wire creates a parallel path to communicate the current to or from the die.

17. The power system of claim 15, wherein the supply voltage pad or the ground pad extends at least partially over a passivation layer.

18. The power system of claim 15, wherein the interior portion includes:
a plurality of supply voltage lines, each of the plurality of supply voltage lines in communication with the supply voltage pad;
a plurality of ground lines, each of the plurality of ground lines in communication with the ground pad, the plurality of ground lines interlaced with the plurality of supply voltage lines;
a plurality of metallized rails disposed across the plurality of supply voltage lines and the plurality of ground lines; and
a via communicatively coupling at least one of the plurality of metallized rails to at least one of the supply voltage lines or at least one of the ground lines.

19. The power grid of claim 18, wherein:
the plurality of metallized rails comprise supply voltage metallized rails and ground metallized rails, each of the supply voltage metallized rails in communication with at least one of the supply voltage lines and each of the ground metallized rails in communication with at least one of the ground lines.

20. The power grid of claim 19, further comprising:
a jumper wire extending between two supply voltage metallized rails or two ground metallized rails to establish communication between the two supply voltage metallized rails or the two ground metallized rails.
